(19) United States
(12) Patent Application Publication
(10) Pub. No.: US 2026/0031707 A1
(43) Pub. Date: Jan. 29, 2026

(54) LOAD-CURRENT-DEPENDENT GATE DRIVER WITH VOLTAGE MODULATION

(71) Applicant: QUALCOMM Incorporated, San Diego, CA (US)

(72) Inventors: Navankur BEOHAR, Chandler, AZ (US); Joseph Dale RUTKOWSKI, Chandler, AZ (US); Edgar MARTI-ARBONA, Chandler, AZ (US)

(21) Appl. No.: 19/267,852

(22) Filed: Jul. 14, 2025

Related U.S. Application Data
(60) Provisional application No. 63/676,838, filed on Jul. 29, 2024.

(51) Int. Cl. H02M 1/088; H02M 1/00; H02M 3/156; H03K 17/687

(52) U.S. Cl. CPC H02M 1/088; H02M 1/0009; H02M 3/156; H03K 17/687

(57) ABSTRACT

Certain aspects of the present disclosure are directed towards a switched-mode power supply (SMPS). The SMPS generally includes a first transistor, an inductive element coupled to the first transistor, and a driver circuit configured to: generate one of a first gate drive voltage and a second gate drive voltage to turn on the first transistor, the one of the first gate drive voltage and the second gate drive voltage being selected based on an output current of the SMPS, wherein the first gate drive voltage is different than the second gate drive voltage; and provide the one of the first gate drive voltage and the second gate drive voltage to a gate of the first transistor.

### CROSS-REFERENCE TO RELATED APPLICATION

This application claims benefit of and priority to U.S. Provisional Application No. 63/676,838 filed on Jul. 29, 2024, which is hereby expressly incorporated by reference herein in its entirety as if fully set forth below and for all applicable purposes.

### FIELD OF THE DISCLOSURE

Certain aspects of the present disclosure generally relate to electronic circuits and, more particularly, to a switched-mode power supply (SMPS)

### BACKGROUND

A voltage regulator ideally provides a constant direct current (DC) output voltage regardless of changes in load current or input voltage. Voltage regulators may be classified as either linear regulators or switching regulators. While linear regulators tend to be small and compact, many applications may benefit from the increased efficiency of a switching regulator. A linear regulator may be implemented by a low-dropout (LDO) regulator, for example. A switching regulator may be implemented by a switched-mode power supply (SMPS), such as a buck converter, a boost converter, or a buck-boost converter.

Power management integrated circuits (power management ICs or PMICs) are used for managing the power demands of a host system and may include and/or control one or more voltage regulators (e.g., boost converters). A PMIC may be used in battery-operated devices, such as mobile phones, tablets, laptops, wearables, etc., to control the flow and direction of electrical power in the devices. The PMIC may perform a variety of functions for the device such as DC-to-DC conversion (e.g., using a voltage regulator as described above), battery charging, power-source selection, voltage scaling, power sequencing, etc. For example, a PMIC may feature a buck converter to perform voltage regulation based on a DC input voltage.

### SUMMARY

Certain aspects of the present disclosure are directed towards a switched-mode power supply (SMPS). The SMPS generally includes: a first transistor, an inductive element coupled to the first transistor, and a driver circuit configured to: generate one of a first gate drive voltage and a second gate drive voltage to turn on the first transistor, the one of the first gate drive voltage and the second gate drive voltage being selected based on an output current of the SMPS, wherein the first gate drive voltage is different than the second gate drive voltage; and provide the one of the first gate drive voltage and the second gate drive voltage to a gate of the first transistor.

Certain aspects of the present disclosure are directed towards an SMPS. The SMPS generally includes: a first transistor, an inductive element coupled to the first transistor, and a driver circuit including an output coupled to a gate of the first transistor and comprising: a first capacitive element including a first terminal selectively coupled to a voltage rail; and a second capacitive element including a first terminal selectively coupled to the first terminal of the first capacitive element, a second terminal of the second capacitive element being coupled to a source of the first transistor.

Certain aspects of the present disclosure are directed towards a method for voltage regulation. The method generally includes: sensing an output current of an SMPS; selecting one of a first gate drive voltage and a second gate drive voltage based on the output current of the SMPS, the first gate drive voltage being different than the second gate drive voltage; generating the one of the first gate drive voltage and the second gate drive voltage based on the selection; and providing the one of the first gate drive voltage and the second gate drive voltage to a gate of a transistor of the SMPS.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a block diagram of an example device including a voltage regulator, in which aspects of the present disclosure may be practiced.

FIGS. 2A and 2B illustrate stacked battery cell and single battery cell configurations, respectively, used to generate voltage rails for a hybrid buck converter, according to certain aspects of the present disclosure.

FIG. 3A shows an example buck converter with a single battery cell configuration, according to certain aspects of the present disclosure.

FIG. 3B shows an example buck converter with a stacked battery cell configuration, according to certain aspects of the present disclosure.

FIGS. 4A, 4B, 5A, 5B, 6A, and 6B illustrate current flows during charge and discharge phases of a buck converter, according to certain aspects of the present disclosure.

FIG. 7 shows an example hybrid buck converter implemented using floating gate drivers, in accordance with certain aspects of the present disclosure

FIG. 8 illustrates an example implementation of a floating driver, in accordance with certain aspects of the present disclosure

FIG. 9 is a flow diagram illustrating example operations for voltage regulation, in accordance with certain aspects of the present disclosure.

FIG. 10 is a flow diagram illustrating example operations for voltage regulation, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed towards a switched-mode power supply (SMPS) using a gate driver to implement voltage modulation. For example, the gate driver may drive a gate of one or more transistors of the SMPS using a first gate drive voltage when an output current of the SMPS is less than or equal to a current threshold to decrease switching losses of the SMPS and increase SMPS efficiency. On the other hand, when the output current of the SMPS is greater than a current threshold, a second gate drive voltage greater than the first gate drive voltage may be used to decrease the on-resistance of the one or more transistors, reduce conduction losses, and increase SMPS efficiency and power delivery. In some implementations, different transistors of the SMPS may have different source voltages. To drive the different transistors, floating drivers may be used to generate the gate drive voltages for the respective transistors of the SMPS with reference to the respective source voltages.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

### An Example Device

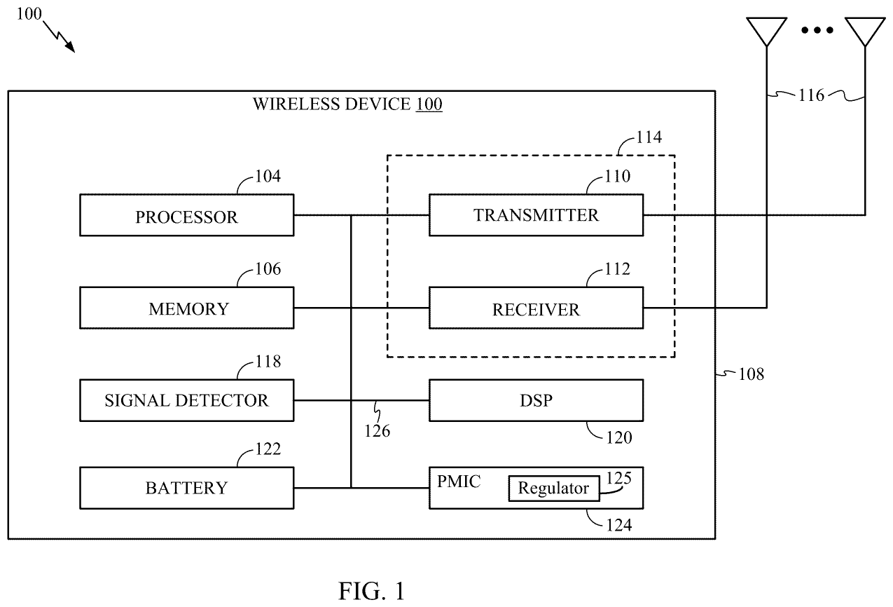

FIG. 1 illustrates a device 100. The device 100 may be a battery-operated and/or wireless device such as a cellular phone, a personal digital assistant (PDA), a handheld device, a wireless modem, a laptop computer, a tablet, a personal computer, a head-mounted or other wearable device, an augmented or virtual reality device, etc. The device 100 is an example of a device that may be configured to implement the various systems and methods described herein.

The device 100 may include at least one processor 104 which controls operation of the device 100. The processor 104 may also be referred to as a central processing unit (CPU). Memory 106, which may include both read-only memory (ROM) and random access memory (RAM), provides instructions and data to the processor 104. A portion of the memory 106 may also include non-volatile random access memory (NVRAM). The processor 104 typically performs logical and arithmetic operations based on program instructions stored within the memory 106. The instructions in the memory 106 may be executable to implement the methods described herein.

The device 100 may also include a housing 108 that may include a transmitter 110 and a receiver 112 to allow transmission and reception of data between the device 100 and a remote location. The transmitter 110 and receiver 112 may be combined into a transceiver 114. A plurality of antennas 116 may be electrically coupled to the transceiver 114. One or more of the antennas 116 may be disposed adjacent to, attached to, or integrated in the housing 108. The device 100 may also include (not shown) multiple transmitters, multiple receivers, and multiple transceivers.

The device 100 may also include a signal detector 118 that may be used in an effort to detect and quantify the level of signals received by the transceiver 114. The signal detector 118 may detect such signals as total energy, energy per subcarrier per symbol, power spectral density and other signals. The device 100 may also include a digital signal processor (DSP) 120 for use in processing signals.

The device 100 may further include a battery 122 used to power the various components of the device 100. The device 100 may also include a power management integrated circuit (power management IC or PMIC) 124 for managing the power provided from the battery to the various components of the device 100. The PMIC 124 may perform a variety of functions for the device such as DC-to-DC conversion (e.g., with a voltage regulator 125, such as a switched-mode power supply (SMPS)), battery charging, power-source selection, voltage scaling, power sequencing, etc. In certain aspects, the voltage regulator 125 may include one or more transistors that may be driven by a floating driver, as described in more detail herein.

The various components of the device 100 may be coupled together by a bus system 126, which may include a power bus, a control signal bus, and a status signal bus in addition to a data bus.

### Example Voltage Regulation System

A stacked battery cell configuration has been introduced to decrease battery charging times and reduce charging losses. A stacked battery cell configuration includes two (referred to as a 2S battery configuration) or more battery cells in series, whereas a single battery cell configuration (referred to as a 1S battery configuration) includes a single battery cell. In many power management unit (PMU) designs, boost or buck-boost converters are the system's performance bottleneck due to the loop bandwidths of the converters. As a result, it is challenging to meet all system specifications such as high speed, large load current, and small bill of materials (BOM).

In a cellular phone platform, for a stacked battery cell configuration, an electronic device may have separate voltage rails (V1 and V2). Each voltage rail can have a wide operation range, e.g., ranging from 2 V to 5.5 V for V1 and 4 V to 11 V for V2. Therefore, a switched-mode power supply (SMPS) configured in a boost mode of operation to convert a low voltage to a high voltage may be used in some corner operation range with some buck-boost or three-level buck-boost architectures. Therefore, the loop bandwidth of the SMPS has to accommodate boost operation, even though the SMPS may be operated in boost mode for only a small portion (e.g., a fifth or half) of the time the SMPS is operated.

Certain aspects use a voltage rail input and a charge pump configuration to eliminate boost or buck-boost operation in an SMPS, allowing operation in only a buck mode to increase bandwidth. For example, certain aspects use the single or stacked battery cell configuration to implement a 4-level hybrid buck operation. Based on an input-to-output conversion ratio (e.g., the ratio of battery voltage to output voltage (Vout)), the SMPS provided herein performs buck operations between a 3S voltage (e.g., three times the 1S voltage) and a 2S voltage (e.g., twice the 1S voltage for a single cell configuration or the 2S voltage for a stacked cell configuration), between 2S and 1S, or between 1S and a reference potential node (e.g., ground (GND)).

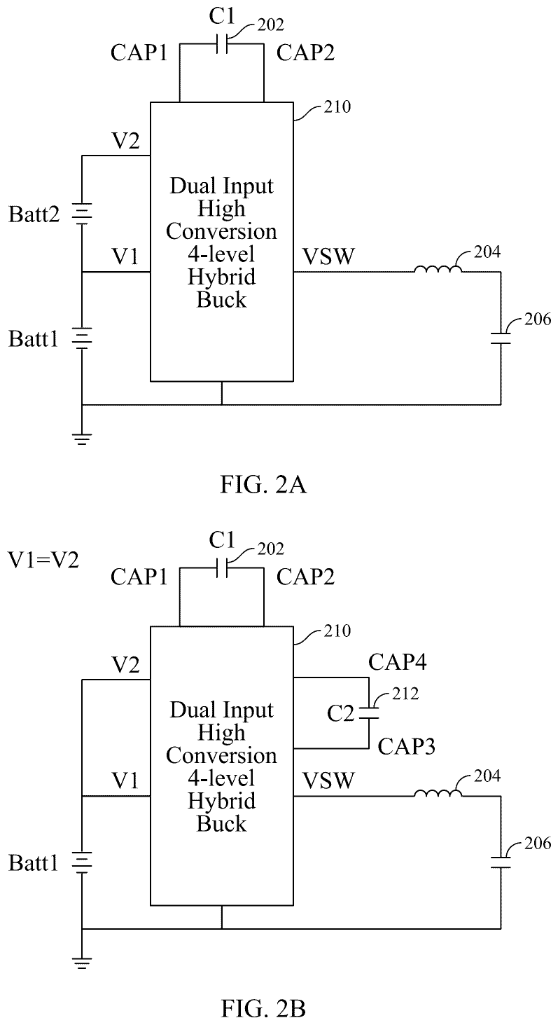

FIGS. 2A and 2B illustrate 2S and 1S battery configurations, respectively, used to generate voltage rails V1 and V2 for a hybrid buck converter. As shown in FIG. 2A, for a 2S battery configuration, a first battery (Batt1) may be used to generate the voltage at rail V1 and a second battery (Batt2) may be used to generate the voltage at rail V2, where the voltage at rail V1 is equal to the battery voltage (Vbatt1) associated with Batt1 and the voltage at rail V2 is equal to Vbatt1 plus the battery voltage (Vbatt2) associated with Batt2. As shown in FIG. 2B, for a 1S battery configuration, Batt1 may be used to provide both V1 and V2 such that V1 is equal to V2, as shown. In other words, voltage rail V1 may be shorted to voltage rail V2, for the 1S battery configuration.

In the 2S battery configuration shown in FIG. 2A, a capacitive element 202 (labeled “C1”), an inductive element 204, and a load capacitive element 206 may be implemented for the buck converter. As shown, the capacitive element 202, the inductive element 204, and the load capacitive element 206 may be external to an IC 210 (labeled “Dual Input High Conversion 4-level Hybrid Buck”) used to implement various switches and other components for the buck operations described herein. The capacitive element 202 is coupled between node CAPI and node CAP2. As shown in FIG. 2B, for the 1S battery configuration, a capacitive element 212 (labeled “C2”) is implemented external to the IC 210 and between node CAP3 and node CAP4. The hybrid buck converters shown in FIGS. 2A and 2B may include the capacitive element 202, the inductive element 204, the load capacitive element 206, and the IC 210, while the 1S battery configuration of FIG. 2B may additionally include the capacitive element 212.

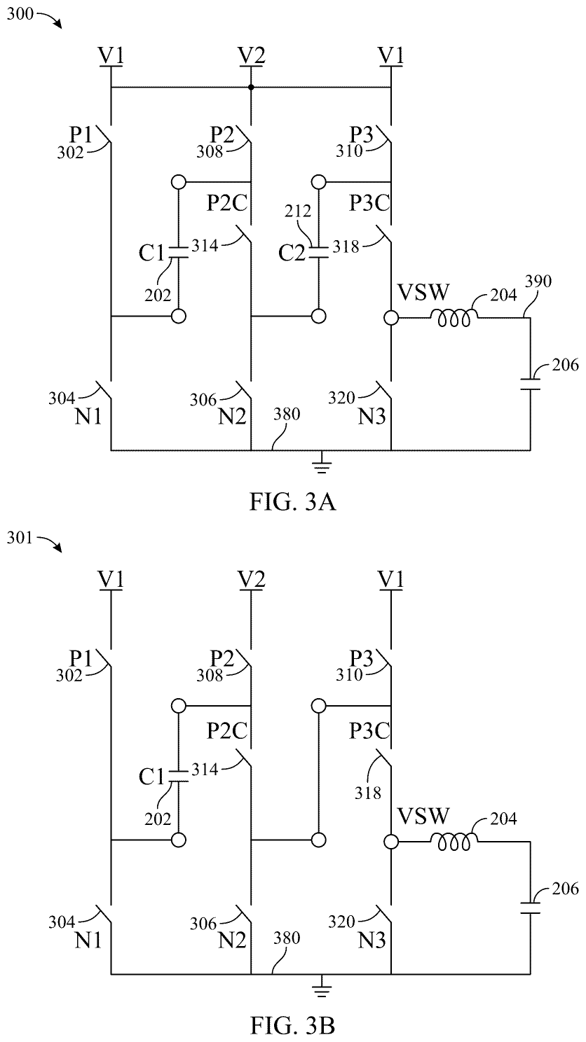

FIG. 3A shows an example hybrid buck converter 300 with a 1S battery configuration (e.g., a single battery cell configuration), and FIG. 3B shows an example hybrid buck converter 301 with a 2S battery configuration (e.g., a stacked battery cell configuration). The hybrid buck converter 300 may be an example implementation of the hybrid buck converter in FIG. 2B for a 1S battery configuration. The hybrid buck converter 301 may be an example implementation of the hybrid buck converter in FIG. 2A for a 2S battery configuration.

As shown in FIG. 3A for the 1S battery configuration, the voltage rails V1 and V2 are shorted together (e.g., effectively forming a single voltage rail). As shown in FIG. 3B for the 2S battery configuration, the voltage rails V1, V2 are separate rails. Switch 310 (labeled “P3”) and switch 318 (labeled “P3C”) are coupled in a series path between rail V1 and a switching node (VSW), where inductive element 204 and load capacitive element 206 are coupled in a series path between VSW and a reference potential node 380 (e.g., electrical ground node). The inductive element 204 is coupled between VSW and an output node 390 of the buck converter. As shown, switch 320 (labeled “N3”) is coupled between VSW and the reference potential node. For certain aspects, switch 318 may be removed and replaced with a short, for example.

Moreover, switch 308 (labeled “P2”), switch 314 (labeled “P2C”), and switch 306 (labeled “N2”) are coupled in a series path between voltage rail V2 (e.g., which is the same as rail V1 for the 1S battery configuration) and the reference potential node 380, and switch 302 (labeled “P1”) and switch 304 (labeled “N1”) are coupled in another series path between voltage rail V1 and the reference potential node. As shown in FIG. 3A for the 1S battery configuration, capacitive element 212 (labeled “C2”) has a first terminal coupled to a node between switches 310, 318 and has a second terminal coupled to a node between switches 306, 314, and capacitive element 202 (labeled “C1”) has a first terminal coupled to a node between switches 308, 314 and has a second terminal coupled to a node between switches 302, 304, as shown. As shown in FIG. 3B for the 2S battery configuration, the node between switches 310, 318 is shorted to the node between switches 306, 314 (e.g., as opposed to being coupled through capacitive element 212, as in FIG. 3A). The switches described herein may be implemented by transistors, such as p-type metal-oxide-semiconductor (PMOS) or n-type metal-oxide-semiconductor (NMOS) transistors.

In certain aspects for the 2S battery configuration, switch 314 may be removed and replaced with a short, for example. Additionally or alternatively in certain aspects for the 2S battery configuration, switch 306 may be removed and replaced with a short, for example.

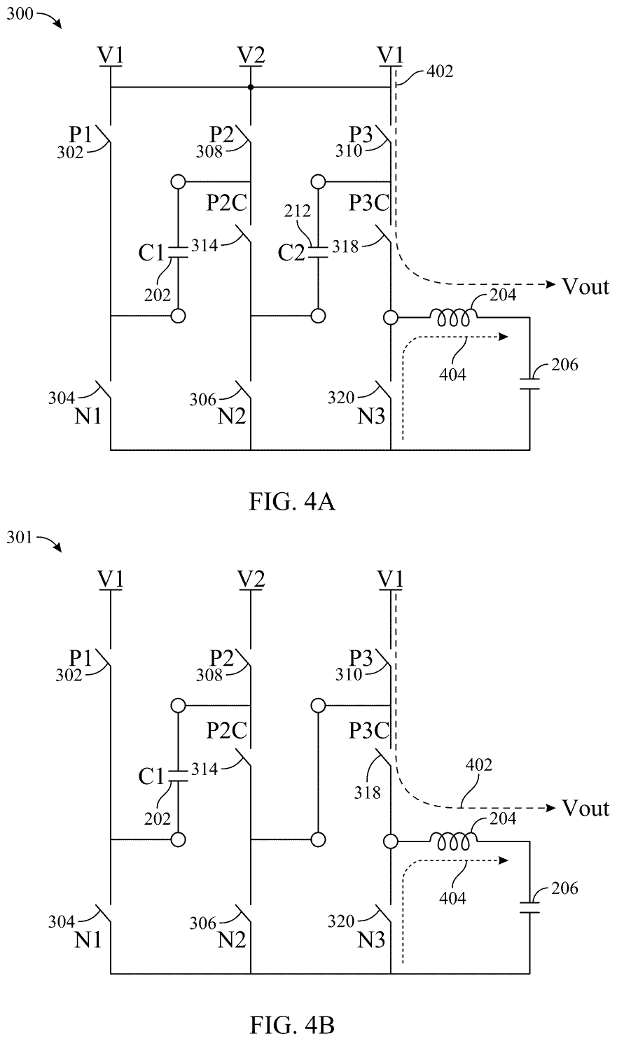

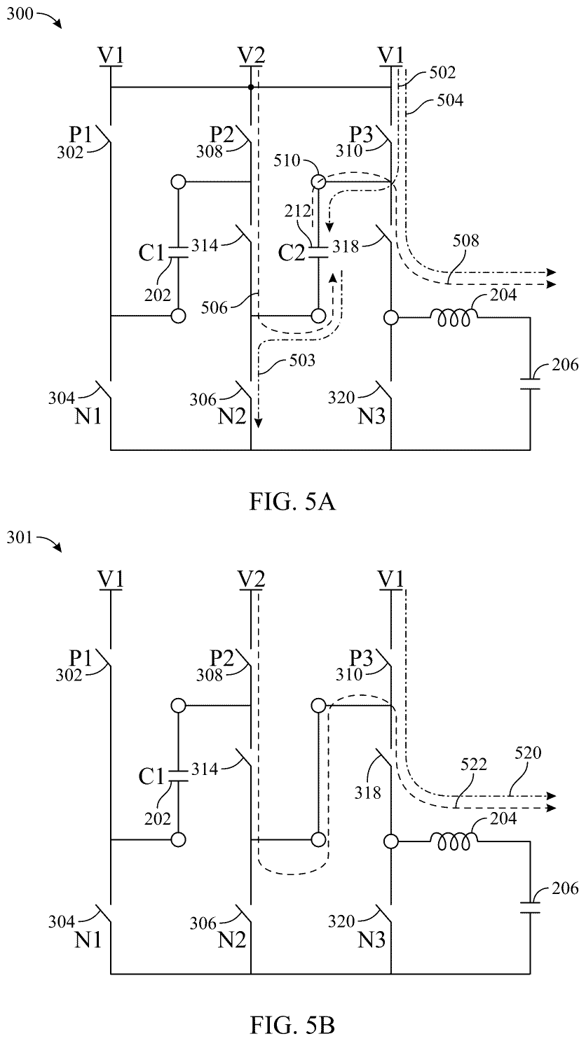

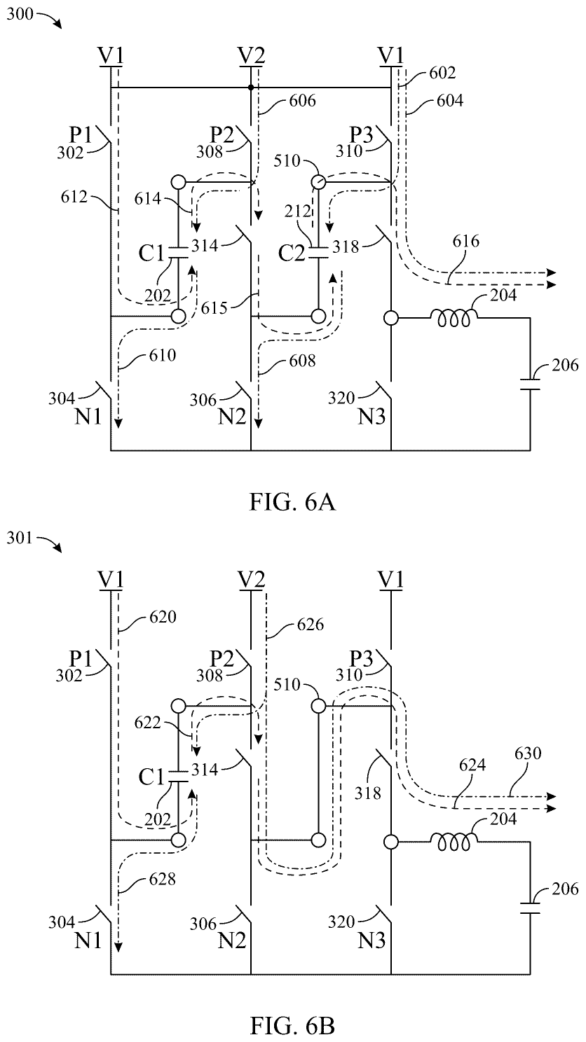

FIG. 4A illustrates current flows during charge and discharge phases when Vout is less than a 1S voltage (e.g., the voltage at rail V1) for the single battery cell configuration. FIG. 4B illustrates current flows during charge and discharge phases when Vout is less than a 1S voltage (e.g., the voltage at rail V1) for the stacked battery cell configuration. The reference potential node 380 and the output node 390 are omitted for simplicity from FIGS. 4A and 4B (as well as from FIGS. 5A-6B), but remain at their respective positions as indicated in FIGS. 3A and 3B. The output voltage Vout corresponds to the voltage at output node 390 (with respect to the reference potential node 380).

Curve 402 shows the current flow during the charge phase, and curve 404 shows the current flow during the discharge phase. When Vout is less than the 1S voltage, switches 310, 318 are closed (not shown) while switch 320 is open during the charge phase, and switch 320 is closed (not shown) while switches 310, 318 are open during the discharge phase, for both the single battery cell configuration shown in FIG. 4A and the stacked battery cell configuration shown in FIG. 4B. During the charge phase, current flows from voltage rail V1 to the inductive element 204, charging the energy stored in inductive element 204. During the discharge phase, current flows from the reference potential node to the inductive element 204, discharging the energy stored in the inductive element 204.

For certain aspects in cases where Vout is less than the 1S voltage, the switches 302, 304, 306, 308, and 314 may be open during the charge and discharge phases.

FIG. 5A illustrates current flow during charge and discharge phases when Vout is greater than the 1S voltage (e.g., the voltage at rail V1) and less than the 2S voltage for the 1S battery cell configuration. FIG. 5B illustrates current flow during charge and discharge phases when Vout is greater than the 1S voltage (e.g., the voltage at rail V1) and less than the 2S voltage for the stacked battery cell configuration. For the 1S battery cell configuration, the 2S voltage may be equal to twice the 1S voltage, and for the 2S battery cell configuration, the 2S voltage may be equal to the voltage of rail V2.

For the 1S battery cell configuration of FIG. 5A, when Vout is greater than the 1S voltage and less than the 2S voltage, switches 310, 318, and 306 are closed (not shown) while switches 308, 314, and 320 are open during the discharge phase, and switches 308, 314, and 318 are closed (not shown) while switches 306, 310, and 320 are open during the charge phase. Curves 502, 503, 504 show the current flow in the hybrid buck converter during the discharge phase, and curves 506, 508 show the current flow in the hybrid buck converter during the charge phase.

As shown by curves 502, 503, 504 in FIG. 5A for the 1S battery cell configuration, during the discharge phase, current flows to the output of the hybrid buck converter and flows across capacitive element 212, charging capacitive element 212 to the 1S voltage. During the charge phase as shown by curves 506, 508, current flows from voltage rail V2 (e.g., equal to voltage rail V1 for the 1S battery cell configuration) across capacitive element 212 in the opposite direction and to the output through the inductive element 204. Thus, the voltage at node 510 between capacitive element 212 and the inductive element 204 during the charge phase has the sum of the 1S voltage and the voltage (e.g., also equal to the 1S voltage) across capacitive element 212 (as voltage rail V2 and capacitive element 212 are in series during the charge phase), which is equal to the 2S voltage (or twice the 1S voltage), allowing regulation in buck mode of Vout to any voltage between the 1S voltage and the 2S voltage.

For the 2S battery cell configuration shown in FIG. 5B, during the discharge phase, switches 310 and 318 are closed (not shown) while switches 306, 308, 314, and 320 are open, and during the charge phase, switches 308, 314, and 318 are closed (not shown) while switches 306, 310, and 320 are open. Curve 520 shows the current flow in the hybrid buck converter during the discharge phase, and curve 522 shows the current flow in the hybrid buck converter during the charge phase. As shown, during the discharge phase, current flows from voltage rail V1 to the inductive element 204 by closing switches 310, 318, resulting in the discharge of energy in inductive element 204 since the voltage at rail V1 is less than Vout. During the charge phase, current flows from voltage rail V2 to inductive element 204 by closing switches 308, 314, 318, charging the energy stored in inductive element 204 since the voltage at voltage rail V2 is greater than Vout.

For certain aspects in cases where Vout is greater than the 1S voltage and less than the 2S voltage, the switches 302 and 304 may be open during the charge and discharge phases.

FIG. 6A illustrates current flows during charge and discharge phases when Vout is greater than the 2S voltage for the 1S battery cell configuration. FIG. 6B illustrates current flows during charge and discharge phases when Vout is greater than the 2S voltage for the stacked battery cell configuration.

For the 1S battery cell configuration, when Vout is greater than the 2S voltage, switches 310, 318, 306, 308, and 304 are closed (not shown) while switches 302, 314, and 320 are open during the discharge phase, and switches 302, 314, and 318 are closed (not shown) while switches 304, 306, 308, 310, and 320 are open during the charge phase. Curves 602, 604, 606, 608, 610 show the current flow in the hybrid buck converter during the discharge phase, and curves 612, 614, 615, 616 show the current flow in the hybrid buck converter during the charge phase.

As shown in FIG. 6A for the 1S battery cell configuration, during the discharge phase, current flows to the output of the hybrid buck converter and flows to capacitive element 212, charging capacitive element 212 to the 1S voltage, and also flows to capacitive element 202, charging capacitive element 202 to the 1S voltage. During the charge phase, current flows from the voltage rail V1 across capacitive elements 202, 212 and to the output through the inductive element 204. Thus, the voltage at node 510 between capacitive element 212 and the inductive element 204 during the charge phase is the sum of the 1S voltage at voltage rail V1, the 1S voltage across capacitive element 202, and the 1S voltage across capacitive element 212, which is equal to 3S (e.g., three times the 1S voltage), allowing regulation in buck mode of Vout to any voltage between the 1S voltage and the 3S voltage. The current flows in FIG. 6A may also represent high load current cases where this 3S capability is selected, even though Vout may be less than two times the 1S voltage.

For the 2S battery cell configuration shown in FIG. 6B, during the discharge phase, switches 308, 314, 318, and 304 are closed (not shown) while switches 302, 306, 310, and 320 are open, and during the charge phase, switches 302, 314, and 318 are closed (not shown) while switches 304, 306, 308, 310, and 320 are open. Curves 626, 628, 630 show the current flows in the hybrid buck converter during the discharge phase, and curves 620, 622, 624 show the current flows in the hybrid buck converter during the charge phase.

During the discharge phase, current flows from voltage rail V2 (e.g., having the 2S voltage) through the capacitive element 202 to the reference potential node (e.g., electrical ground node). Thus, the capacitive element 202 is charged to the 2S voltage due to the current flow from voltage rail V2. Current also flows from the voltage rail V2 to the output through switches 308, 314, 318, and inductive element 204 during the discharge phase. During the charge phase, the voltage at node 510 between capacitive element 202 and the inductive element 204 is the sum of the 1S voltage of the voltage rail V1 and the 2S voltage across capacitive element 202, which is equal to the 3S voltage (e.g., the 2S voltage plus the 1S voltage), allowing regulation in buck mode of Vout to any voltage between the 2S voltage and the 3S voltage. Furthermore and similar to the 1S case of FIG. 6A, the mode of operation in FIG. 6B may be selected when Vout is less than the 2S voltage (e.g., for high load current cases).

Certain aspects described herein facilitate operation of a voltage regulator in buck mode regardless of whether Vout is below the 1S voltage, between the 1S voltage and 2S voltage, or greater than the 2S voltage. Operation in buck mode allows an increase in the bandwidth associated with the SMPS as compared to conventional SMPS implementations that may at least partly operate in a boost or buck-boost mode.

### Example Apparatus for Voltage Regulation

Certain aspects of the present disclosure are directed to a switched-mode power supply (SMPS) (e.g., the hybrid buck converter 300 or 301). The SMPS includes: an inductive element (e.g., inductive element 204) coupled to an output of the SMPS; a first switch (e.g., switch 310); a second switch (e.g., switch 318), wherein the first switch is coupled between a first voltage rail and the second switch, and wherein the second switch is coupled between the first switch and the inductive element; a third switch (e.g., switch 320) coupled between the inductive element and a reference potential node; a fourth switch (e.g., switch 308); a fifth switch (e.g., switch 314), wherein the fourth switch is coupled between a second voltage rail and the fifth switch, and wherein the fifth switch is coupled between the fourth switch and the second switch; and a sixth switch (e.g., switch 306) coupled between the fifth switch and the reference potential node. In some aspects, the first voltage rail is shorted to the second voltage rail.

In some aspects, the SMPS also includes a capacitive element (e.g., capacitive element 212). The fifth switch may be coupled between the fourth switch and the second switch through the capacitive element.

In some aspects, the SMPS includes a seventh switch (e.g., switch 302) and an eighth switch (e.g., switch 304). The seventh switch may be coupled between the first voltage rail and the eighth switch, and the eighth switch may be coupled between the seventh switch and the reference potential node. The SMPS may also include a first capacitive element (e.g., capacitive element 202) coupled between the seventh switch and the fifth switch. In some aspects, when a voltage at the output of the SMPS is greater than a first voltage at the first voltage rail and, in some cases, greater than a second voltage (e.g., as described with respect to FIGS. 6A and 6B), a first current (e.g., shown by curve 606 in FIG. 6A or curve 626 in FIG. 6B) is configured to flow from the second voltage rail to the reference potential node through the fourth switch, the first capacitive element, and the eighth switch during a discharge phase. Moreover, a second current (e.g., shown by curves 612, 614, 616 in FIG. 6A, or curves 620, 622, 624 in FIG. 6B) is configured to flow from the first voltage rail to the inductive element through the seventh switch, the first capacitive element, the fifth switch, and the second switch during a charge phase. In some aspects, the second voltage is a voltage at the second voltage rail (e.g., for the 2S battery cell configuration). In some aspects, when the voltage at the output of the SMPS is greater than the first voltage and greater than the second voltage at the second voltage rail, a third current (e.g., shown by curve 630 in FIG. 6B) is configured to flow from the second voltage rail to the inductive element through the fourth switch, the fifth switch, and the second switch during the discharge phase. In some aspects, the SMPS also includes a second capacitive element (e.g., capacitive element 212), the fifth switch being coupled between the fourth switch and the second switch through the second capacitive element. When the voltage at the output of the SMPS is greater than the first voltage at the first voltage rail and greater than twice the first voltage (e.g., for the 1S battery cell configuration), a third current (e.g., shown by curves 602, 608) is configured to flow from the first voltage rail to the reference potential node through the first switch, the second capacitive element, and the sixth switch during the discharge phase, and the second current is further configured to flow to the inductive element through the second capacitive element.

Any of the first through eighth switches may be implemented by one or more transistors. These transistors may be either p-type transistors, n-type transistors, or a combination of p-type and n-type transistors.

In some aspects, when a voltage at the output of the SMPS is less than a voltage at the first voltage rail (e.g., as shown in FIGS. 4A and 4B), a first current (e.g., shown by 402) is configured to flow from the first voltage rail to the inductive element through the first switch and the second switch during a charge phase. Moreover, a second current (e.g., shown by curve 404) is configured to flow from the reference potential node to the inductive element through the third switch during a discharge phase.

In some aspects, when a voltage at the output of the SMPS is greater than a first voltage (e.g., at the first voltage rail) and less than a second voltage (e.g., as described with respect to FIGS. 5A and 5B), a first current (e.g., shown by curve 504 of FIG. 5A or curve 520 of FIG. 5B) is configured to flow from the first voltage rail to the inductive element through the first switch and the second switch during a discharge phase, and a second current (e.g., shown by curves 506, 508 of FIG. 5A or curve 522 of FIG. 5B) is configured to flow from the second voltage rail to the inductive element through the fourth switch, the fifth switch, and the second switch during a charge phase. In some aspects, the second voltage is a voltage at the second voltage rail.

In some aspects, the SMPS also includes a capacitive element (e.g., capacitive element 212), the fifth switch being coupled between the fourth switch and the second switch through the capacitive element. When the voltage at the output of the SMPS is greater than the first voltage (e.g., at the first voltage rail) and less than twice the first voltage, a third current (e.g., shown by curves 502, 503) is configured to flow from the first voltage rail to the reference potential node through the first switch, the capacitive element, and the sixth switch during the discharge phase. In this case, the second current (e.g., shown by curves 506, 508) is configured to flow from the second voltage rail to the inductive element through the capacitive element during the charge phase.

### Example Voltage Regulation Circuitry with Increased Efficiency

Certain aspects of the present disclosure are directed toward techniques for increasing the efficiency and power delivery performance of a switched-mode power supply (SMPS), such as a 4-level hybrid buck converter (e.g., converter 300 of FIG. 3). The techniques described herein also allow for a reduction of the silicon area used to deliver a certain amount of power. Certain aspects of the present disclosure may be applied to any suitable switching converter type, such as a buck, boost, buck-or-boost (BoB), or inverted buck-or-boost converter. Certain aspects provide a driver used to drive one or more power field-effect transistors (FETs) of an SMPS. To increase the efficiency of the SMPS at light load currents, the switching losses may be reduced, resulting in increased efficiency. Power delivery may be increased at high load currents by reducing conduction losses. To reduce the conduction losses, the on-resistance (R_{ds,on}) of each power FET may be reduced by increasing the gate drive voltage of the power FET. However, increasing the gate drive voltage of the power FET may increase switching losses. Thus, at light load currents, the gate drive voltage of the power FET may be reduced,

Certain aspects use one or more floating gate drivers that may be powered from a boost voltage (Vboost) rail to generate one or more gate drive voltages to drive one or more power FETs of the SMPS. For example, a first mode of operation (e.g., referred to as a “low R_{ds,on} mode (LRM)”) may be used when operating at high load currents (e.g., a load current greater than a current threshold). At low load currents where switching losses are dominant, a gate drive voltage V_{gs} that provides reduced switching losses may be used to drive the power FETs. At high load currents where conduction losses are dominant, a higher gate drive voltage V_{gs,LRM} may be used to drive the power FETs to reduce the R_{ds,on} leading to higher efficiency, higher power delivery, and/or reduced silicon area to deliver a certain amount of power (e.g., since a smaller power FET may be used to drive the same amount of power). Certain aspects increase the power density of the SMPS. Current sensing information may be used to distinguish between low-load current and high-load current scenarios and to switch between the two gate drive voltages V_{gs} and V_{gs,LRM}.

To drive power FETs for the 4-level hybrid buck converter, Vboost may be generated, where Vboost is equal to VPH1 plus V_{gs}. VPH1 may be the supply voltage of the converter, and V_{gs} may be the gate-to-source voltage to be applied for a respective power FET. Moreover, floating gate drivers may be used to generate different gate drive voltages for different power FETs of the converter, such as (i) a gate drive voltage equal to two times VPH1 plus V_{gs} and (ii) a gate drive voltage equal to three times VPH1 plus V_{gs}. Similarly, to reduce the conduction losses at high load currents, gate drive voltages equal to VPH1 plus V_{gs,LRM}, two times VPH1 plus V_{gs,LRM}, and three times VPH1 plus V_{gs,LRM} may be generated. That is, depending on the power FET and the supply voltage, the source voltage of the power FET may be at different voltage levels. Thus, different gate drive voltages may be generated to drive the power FETs. In some aspects, a floating gate driver (also referred to as a “floating driver” for short) may be used to generate a respective gate drive voltage with reference to the source voltage of the respective power FET being driven. That is, each floating gate driver may be coupled to and receive a voltage at a source of a transistor to generate a gate voltage for the transistor that is in reference to the source voltage.

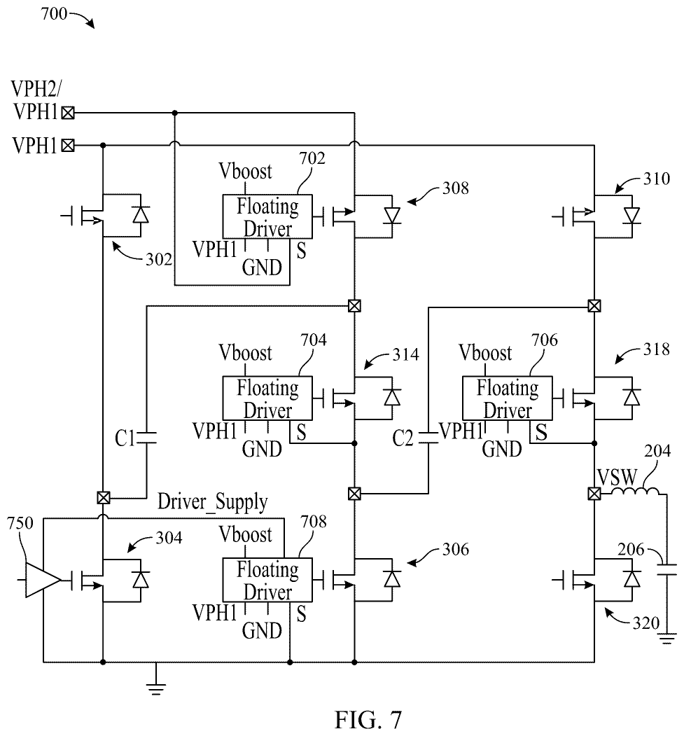

FIG. 7 shows an example of a hybrid buck converter 700 implemented using floating gate drivers, in accordance with certain aspects of the present disclosure. As shown, switches 302, 310 may be provided a first supply voltage VPH1 (e.g., corresponding to voltage V1 shown in FIG. 6B), whereas the switch 308 may be provided either VPH1 or a second supply voltage VPH2 (e.g., corresponding to voltage V2 shown in FIG. 6B) that may be twice VPH1.

As shown, each of the switches 302, 304, 306, 308, 310, 314, 318, 320 may be implemented with a power FET. A floating driver may be used to drive (e.g., control with a suitable voltage) one or more of the power FETs (e.g., switches). For example, floating gate drivers 702, 704, 706, 708 may be used to control switches 308, 314, 318, 306, respectively. Each floating driver may include an input coupled to a source of a respective power FET. For example, the floating driver 706 may include an input (labeled “S”) coupled to a source of a power FET implementing switch 318, as shown. Each floating driver may also receive VPH1 and a Vboost, where Vboost is equal to VPH1 plus V_{gs}. Each floating driver may generate a gate drive voltage equal to either V_{gs} or V_{gs,LRM}. depending on the load current of the converter 700, as described. V_{gs,LRM} may be greater than V_{gs} to provide reduced R_{ds,on} for the associated FET during high-load conditions.

In some aspects, a gate drive voltage generated by a floating driver may be used to drive multiple power FETs. For example, the floating driver 708 may generate a gate drive voltage that is provided to a gate of the FET implementing switch 306 and to a driver supply node (labeled “Driver_supply”). The driver supply node may be coupled to a supply input of driver 750. In other words, in addition to driving the power FET implementing switch 306, the gate drive voltage from the floating driver 708 may be provided to a supply voltage for the driver 750, where the driver 750 is used to drive the FET implementing switch 304, as shown.

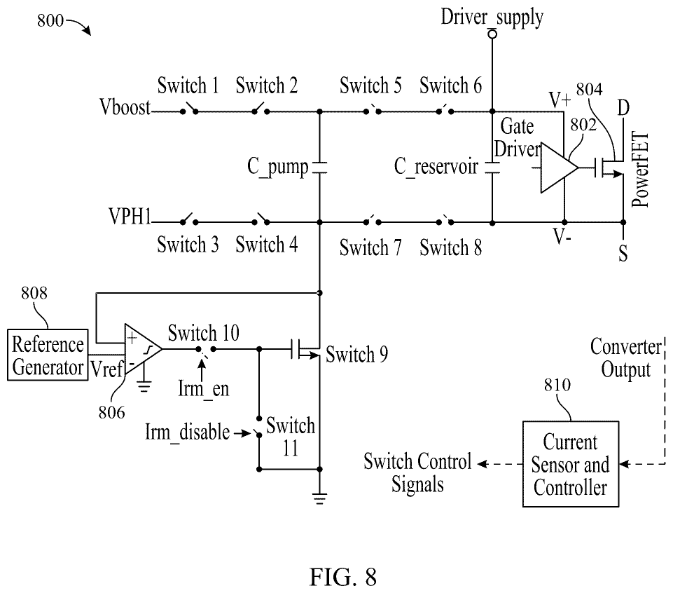

FIG. 8 illustrates an example implementation of a floating driver 800, in accordance with certain aspects of the present disclosure. As shown, the floating driver 800 may include (i) at least one switch (e.g., switches labeled “Switch 1” and “Switch 2”) coupled between a Vboost node and a first terminal of a pump capacitive element (C_pump) and (ii) at least one switch (e.g., switches labeled “Switch 3” and “Switch 4”) coupled between a VPH1 node and a second terminal of C_pump. Moreover, at least one switch (e.g., switches labeled “Switch 5” and “Switch 6”) may be coupled between the first terminal of C_pump and a first terminal of a reservoir capacitive element (C_reservoir). At least one switch (e.g., switches labeled “Switch 7” and “Switch 8”) may be coupled between the second terminal of C_pump and a second terminal of C_reservoir.

The floating driver 800 may also include a gate driver 802. The gate driver 802 may have an input driven by an input signal to drive a power FET 804 (where the power FET 804 is external to the floating driver 800). The power FET 804 may correspond to any of the power FETs used to implement the switches of the hybrid buck converter 700. The gate driver 802 may have a first supply node (e.g., a positive supply input) coupled to the first terminal of C_reservoir and a second supply node (e.g., a negative supply input) coupled to the second terminal of C_reservoir. The second supply input may correspond to the floating driver input labeled “S” in FIG. 7. Depending on the input signal to the driver 802, the gate driver 802 may drive the gate of FET 804 via a voltage at the level of the positive or negative supply input.

As shown, the floating driver 800 may include a switch (labeled “Switch 9,” implemented via a FET) coupled between the second terminal of C_pump and a reference potential node (e.g., electric ground (GND)) for the converter. As shown, a switch (e.g., labeled “Switch 10”) may be coupled between an output of a comparator 806 and a gate of the FET used to implement switch 9. A switch (labeled “Switch 11”) may be coupled between the gate and source of the FET used to implement switch 9.

The floating driver 800 may generate V_{gs} when the load current of the converter (e.g., converter 700) is less than a current threshold. To generate V_{gs}, switches 1-4 and 11 may be closed, and other switches of the floating driver 800 may be opened. In this configuration, the Vboost node may be coupled to the first terminal of C_pump, and the VPH1 node may be coupled to the second terminal of C_pump. Thus, the voltage across C_pump may be equal to Vboost minus VPH1 which may be equal to V_{gs} (e.g., since Vboost is equal to VPH1 plus V_{gs}). Once C_pump is charged to V_{gs}, switches 1-4 may be opened, and switches 5-8 may be closed, sampling the voltage on C_pump by transferring the charge from C_pump to C_reservoir. Thus, after sampling the voltage on C_pump, the voltage across C_reservoir may be equal to V_{gs}. As shown, the second terminal of C_reservoir is coupled to the negative terminal of the gate driver 802 and the source of FET 804. Thus, the negative supply input voltage of the gate driver 802 may be equal to the source voltage of FET 804, and the positive supply input voltage (e.g., at node labeled “driver_supply”) of the gate driver 802 may be equal to V_{gs} plus the source voltage so that the gate driver 802 can drive the FET 804 with V_{gs} (e.g., V_{gs} with reference to the source voltage of FET 804).

The floating driver 800 may generate V_{gs,LRM} when the load current of the converter is greater than or equal to the current threshold. To generate V_{gs,LRM}, switches 1, 2, 9, and 10 may be closed, and the other switches may be open. For example, switch 10 may be closed using a logic high on an LRM enable (lrm_en) signal, and switch 11 may be opened using a logic low on an LRM disable (lrm_disable) signal.

A negative input of the comparator 806 may be provided a reference voltage (Vref) via a reference generator 808, where a positive input of the comparator 806 is coupled to the second terminal of C_pump. The comparator 806 may control the gate of the FET implementing switch 9 to effectively set the voltage at the second terminal of C_pump to Vref. That is, the first terminal of C_pump may be set to Vboost (e.g., VPH1 plus V_{gs}), and the voltage at the second terminal of C_pump may be pulled down via switch 9 and may eventually be effectively set to Vref generated via the reference generator 808 such that the voltage across C_pump is equal to Vboost minus Vref. The comparator 806 may open switch 9 when the voltage at the second terminal of C_pump is equal to Vref. Vboost minus Vref across C_pump may be used as V_{gs,LRM} to drive the FET 804. Once the voltage across C_pump has been set to Vboost minus Vref (e.g., the output of the comparator 806 has been triggered to open switch 9), switches 5-8 and 11 are closed, and the other switches are opened to sample and store V_{gs,LRM} on C_reservoir. Thus, the driver_supply node may be set to V_{gs,LRM} plus the source voltage of the FET 804 and used to drive the FET 804.

With the floating driver, the driving of the FET may be agnostic of the source voltage on the FET. In other words, to turn on the FET 804, the gate driver 802 may drive the gate of the FET with a voltage (e.g., driver_supply voltage) equal to V_{gs} (or V_{gs,LRM}) plus the source voltage. Therefore, regardless of the source voltage, the gate-to-source voltage of the FET 804 may be set to V_{gs} or V_{gs,LRM}. To turn off the FET 804, the gate driver 802 may drive the gate of the FET 804 with a voltage equal to the source voltage of the FET 804.

Certain aspects provide a floating driver powered from Vboost to drive power FETs without generating a voltage rail higher than Vboost (e.g., since the floating driver generates the gate drive voltage with reference to the source voltage of the respective FET). Depending on the load current, the floating driver may modulate the gate drive voltage between V_{gs} and V_{gs,LRM}. In some cases, a current sensor and controller 810 may be used to sense the output current (e.g., current across inductive element 204) of the converter 700 and control the switches of the driver 800 (e.g., switches 1-8, 10, and 11) based on the sensed output current. For example, suppose the average output current of the converter 700 is less than or equal to a current threshold. In that case, V_{gs} may be used to drive one or more FETs of the converter. If the average output current of the converter 700 is greater than the current threshold, V_{gs,LRM} may be used to drive the one or more FETs.

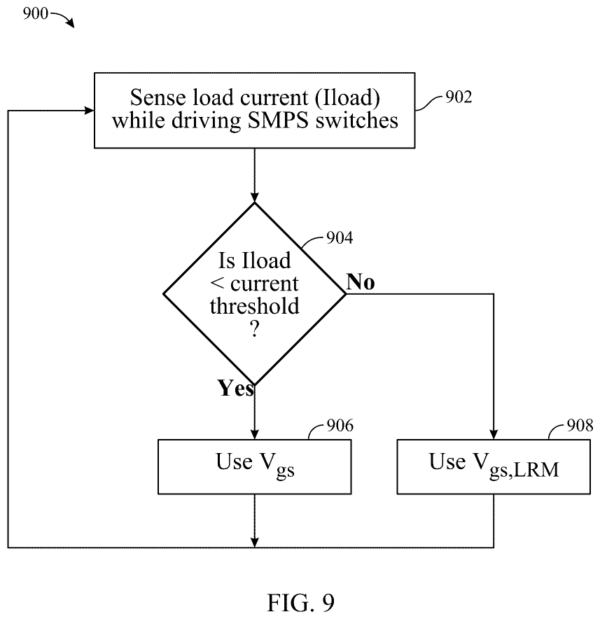

FIG. 9 is a flow diagram illustrating example operations 900 for voltage regulation, in accordance with certain aspects of the present disclosure. The operations 900 may be performed, for example, by a controller such as the controller 810.

At block 902, the controller may sense the load current (Iload) of the SMPS, such as the load current of the hybrid buck converter 300, converter 301, or converter 700. At block 904, the controller may determine whether Iload is less than a current threshold. If so, at block 906, the controller may control one or more floating drivers of the SMPS to generate V_{gs} with LRM disabled. Otherwise, at block 908, the controller may control the one or more drivers of the SMPS to generate V_{gs,LRM} with LRM enabled.

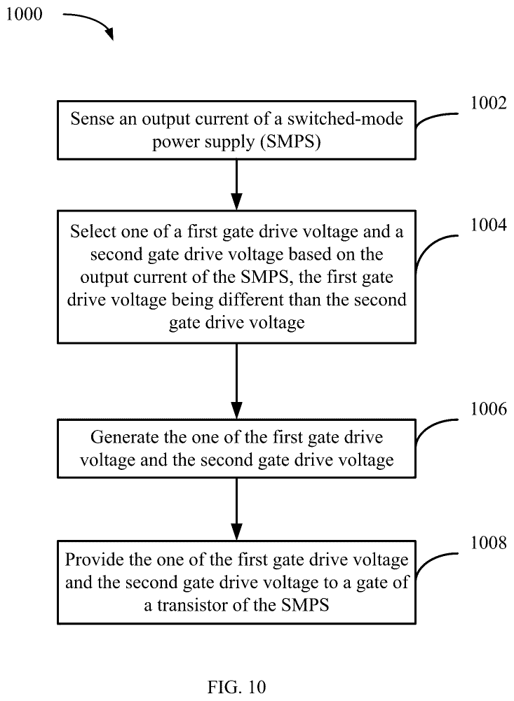

FIG. 10 is a flow diagram illustrating example operations 1000 for voltage regulation, in accordance with certain aspects of the present disclosure. The operations 1000 may be performed, for example, via a switched-mode power supply (SMPS) such as the converter 700 of FIG. 7 including a floating driver such as the floating driver 800 of FIG. 8 and a controller such as the controller 810.

At block 1002, the controller 810 may sense an output current (e.g., current across inductive element 204) of the SMPS. At block 1004, the controller may select one of a first gate drive voltage (e.g., a source voltage of FET 804 plus V_{gs}) and a second gate drive voltage (e.g., a source voltage of FET 804 plus V_{gs,LRM}) based on the output current of the SMPS. The first gate drive voltage may be different (e.g., lower) than the second gate drive voltage. At block 1006, the SMPS may generate the one of the first gate drive voltage and the second gate drive voltage based on the selection. At block 1008, the SMPS may provide the one of the first gate drive voltage and the second gate drive voltage to a gate of a transistor (e.g., FET 804) of the SMPS.

In some aspects, selecting the one of the first gate drive voltage and the second gate drive voltage may include selecting the first gate drive voltage based on the output current of the SMPS being less than or equal to a first current threshold or selecting the second gate drive voltage based on the output current of the SMPS being greater than the first current threshold, the second gate drive voltage being greater than the first gate drive voltage. The first gate drive voltage may include a source voltage of the transistor plus a first preconfigured voltage (e.g., gate-to-source voltage (V_{gs})). The second gate drive voltage may include a source voltage of the transistor plus a second preconfigured voltage (e.g., an adjusted V_{gs} (e.g., V_{gs,LRM})), the second preconfigured voltage being greater than the first preconfigured voltage.

Generating the one of the first gate drive voltage and the second gate drive voltage may include: storing the one of the first gate drive voltage and the second gate drive voltage on a first capacitive element (e.g., C_pump shown in FIG. 8), and sampling the one of the first gate drive voltage and the second gate drive voltage stored on the first capacitive element onto a second capacitive element (e.g., C_reservoir shown in FIG. 8) to yield a sampled voltage. The one of the first gate drive voltage and the second gate drive voltage may be generated based on the sampled voltage.

### Example Aspects

In addition to the various aspects described above, specific combinations of aspects are within the scope of the disclosure, some of which are detailed below:

Aspect 1: A switched-mode power supply (SMPS) comprising: a first transistor; an inductive element coupled to the first transistor; and a driver circuit configured to: generate one of a first gate drive voltage and a second gate drive voltage to turn on the first transistor, the one of the first gate drive voltage and the second gate drive voltage being selected based on an output current of the SMPS, wherein the first gate drive voltage is different than the second gate drive voltage; and provide the one of the first gate drive voltage and the second gate drive voltage to a gate of the first transistor.

Aspect 2: The SMPS of Aspect 1, wherein the driver circuit is configured to: generate the first gate drive voltage based on the output current of the SMPS being less than or equal to a first current threshold; or generate the second gate drive voltage based on the output current of the SMPS being greater than the first current threshold, the second gate drive voltage being greater than the first gate drive voltage.

Aspect 3: The SMPS of Aspect 2, wherein the first gate drive voltage comprises a source voltage of the first transistor plus a first preconfigured voltage.

Aspect 4: The SMPS of Aspect 3, wherein the second gate drive voltage comprises the source voltage of the first transistor plus a second preconfigured voltage, the second preconfigured voltage being greater than the first preconfigured voltage.

Aspect 5: The SMPS of Aspect 4, wherein the SMPS is configured to receive a supply voltage, and wherein the second preconfigured voltage comprises the supply voltage plus the first preconfigured voltage minus a reference voltage.

Aspect 6: The SMPS according to any of Aspects 1-5, wherein the driver circuit comprises: at least one first switch coupled between a voltage rail and a first terminal of a first capacitive element, the SMPS being configured to receive a supply voltage at a supply node, wherein the voltage rail is configured to have a voltage that is higher than the supply voltage of the SMPS by a preconfigured voltage; at least one second switch coupled between the supply node of the SMPS and a second terminal of the first capacitive element; at least one third switch coupled between the first terminal of the first capacitive element and a first terminal of a second capacitive element; at least one fourth switch coupled between the second terminal of the first capacitive element and a second terminal of the second capacitive element; and a driver including a first supply node and a second supply node coupled to the first terminal and the second terminal of the second capacitive element, respectively, and an output coupled to the gate of the first transistor.

Aspect 7: The SMPS of Aspect 6, wherein the driver circuit further comprises: a second transistor coupled between the second terminal of the first capacitive element and a reference potential node; and a comparator including a first input coupled to a reference voltage (Vref) node, a second input coupled to the second terminal of the first capacitive element, and an output coupled to a gate of the second transistor.

Aspect 8: The SMPS of Aspect 7, wherein the driver circuit further comprises a fifth switch coupled between the output of the comparator and the gate of the second transistor.

Aspect 9: The SMPS of Aspect 7 or 8, wherein the driver circuit further comprises a fifth switch coupled between the gate and a source of the second transistor.

Aspect 10: The SMPS of claim 1, wherein the driver circuit is configured to: store the one of the first gate drive voltage and the second gate drive voltage on a first capacitive element; and sample the one of the first gate drive voltage and the second gate drive voltage stored on the first capacitive element onto a second capacitive element to yield a sampled voltage, wherein the one of the first gate drive voltage and the second gate drive voltage is generated based on the sampled voltage.

Aspect 11: A switched-mode power supply (SMPS) comprising: a first transistor; an inductive element coupled to the first transistor; and a driver circuit including an output coupled to a gate of the first transistor and comprising: a first capacitive element including a first terminal selectively coupled to a voltage rail; and a second capacitive element including a first terminal selectively coupled to the first terminal of the first capacitive element, a second terminal of the second capacitive element being coupled to a source of the first transistor.

Aspect 12: The SMPS according to any of Aspects 11-11, wherein the driver circuit further comprises: at least one first switch coupled between the voltage rail and the first terminal of the first capacitive element, the SMPS being configured to receive a supply voltage at a supply node, wherein the voltage rail is configured to have a voltage that is higher than the supply voltage of the SMPS by a preconfigured voltage; at least one second switch coupled between the supply node of the SMPS and a second terminal of the first capacitive element; at least one third switch coupled between the first terminal of the first capacitive element and the first terminal of the second capacitive element; at least one fourth switch coupled between the second terminal of the first capacitive element and the second terminal of the second capacitive element; and a driver including a first supply node and a second supply node coupled to the first terminal and the second terminal of the second capacitive element, respectively, and an output coupled to the gate of the first transistor.

Aspect 13: The SMPS according to any of Aspects 12-12, wherein the driver circuit further comprises: a second transistor coupled between the second terminal of the first capacitive element and a reference potential node; and a comparator including a first input coupled to a reference voltage (Vref) node, a second input coupled to the second terminal of the first capacitive element, and an output coupled to the gate of the second transistor.

Aspect 14: The SMPS according to any of Aspects 13-13, wherein the driver circuit further comprises a fifth switch coupled between the output of the comparator and the gate of the second transistor.

Aspect 15: The SMPS of Aspect 13, wherein the driver circuit further comprises a fifth switch coupled between the gate and a source of the second transistor.

Aspect 16: A method for voltage regulation, comprising: sensing an output current of a switched-mode power supply (SMPS); selecting one of a first gate drive voltage and a second gate drive voltage based on the output current of the SMPS, the first gate drive voltage being different than the second gate drive voltage; generating the one of the first gate drive voltage and the second gate drive voltage based on the selection; and providing the one of the first gate drive voltage and the second gate drive voltage to a gate of a transistor of the SMPS.

Aspect 17: The method according to any of Aspects 16-16, wherein selecting the one of the first gate drive voltage and the second gate drive voltage comprises: selecting the first gate drive voltage based on the output current of the SMPS being less than or equal to a first current threshold; or selecting the second gate drive voltage based on the output current of the SMPS being greater than the first current threshold, the second gate drive voltage being greater than the first gate drive voltage.

Aspect 18: The method according to any of Aspects 17-17, wherein the first gate drive voltage comprises a source voltage of the transistor plus a first preconfigured voltage.

Aspect 19: The method according to any of Aspects 18-18, wherein the second gate drive voltage comprises the source voltage of the transistor plus a second preconfigured voltage for the transistor, the second preconfigured voltage being greater than the first preconfigured voltage.

Aspect 20: The method according to any of Aspects 16-19, wherein generating the one of the first gate drive voltage and the second gate drive voltage comprises: storing the one of the first gate drive voltage and the second gate drive voltage on a first capacitive element; and sampling the one of the first gate drive voltage and the second gate drive voltage stored on the first capacitive element onto a second capacitive element to yield a sampled voltage, wherein the one of the first gate drive voltage and the second gate drive voltage is generated based on the sampled voltage. The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the physical (PHY) layer. In the case of a user terminal, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC with the processor, the bus interface, the user interface in the case of an access terminal), supporting circuitry, and at least a portion of the machine-readable media integrated into a single chip, or with one or more FPGAs, PLDs, controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. A switched-mode power supply (SMPS) comprising:
a first transistor;
an inductive element coupled to the first transistor; and
a driver circuit configured to:
generate one of a first gate drive voltage and a second gate drive voltage to turn on the first transistor, the one of the first gate drive voltage and the second gate drive voltage being selected based on an output current of the SMPS, wherein the first gate drive voltage is different than the second gate drive voltage; and
provide the one of the first gate drive voltage and the second gate drive voltage to a gate of the first transistor.

2. The SMPS of claim 1, wherein the driver circuit is configured to:
generate the first gate drive voltage based on the output current of the SMPS being less than or equal to a first current threshold; or
generate the second gate drive voltage based on the output current of the SMPS being greater than the first current threshold, the second gate drive voltage being greater than the first gate drive voltage.

3. The SMPS of claim 2, wherein the first gate drive voltage comprises a source voltage of the first transistor plus a first preconfigured voltage.

4. The SMPS of claim 3, wherein the second gate drive voltage comprises the source voltage of the first transistor plus a second preconfigured voltage, the second preconfigured voltage being greater than the first preconfigured voltage.

5. The SMPS of claim 4, wherein the SMPS is configured to receive a supply voltage, and wherein the second preconfigured voltage comprises the supply voltage plus the first preconfigured voltage minus a reference voltage.

6. The SMPS of claim 1, wherein the driver circuit comprises:
at least one first switch coupled between a voltage rail and a first terminal of a first capacitive element, the SMPS being configured to receive a supply voltage at a supply node, wherein the voltage rail is configured to have a voltage that is higher than the supply voltage of the SMPS by a preconfigured voltage;
at least one second switch coupled between the supply node of the SMPS and a second terminal of the first capacitive element;
at least one third switch coupled between the first terminal of the first capacitive element and a first terminal of a second capacitive element;
at least one fourth switch coupled between the second terminal of the first capacitive element and a second terminal of the second capacitive element; and
a driver including a first supply node and a second supply node coupled to the first terminal and the second terminal of the second capacitive element, respectively, and an output coupled to the gate of the first transistor.

7. The SMPS of claim 6, wherein the driver circuit further comprises:
a second transistor coupled between the second terminal of the first capacitive element and a reference potential node; and
a comparator including a first input coupled to a reference voltage (Vref) node, a second input coupled to the second terminal of the first capacitive element, and an output coupled to a gate of the second transistor.

8. The SMPS of claim 7, wherein the driver circuit further comprises a fifth switch coupled between the output of the comparator and the gate of the second transistor.

9. The SMPS of claim 7, wherein the driver circuit further comprises a fifth switch coupled between the gate and a source of the second transistor.

10. The SMPS of claim 1, wherein the driver circuit is configured to:
store the one of the first gate drive voltage and the second gate drive voltage on a first capacitive element; and
sample the one of the first gate drive voltage and the second gate drive voltage stored on the first capacitive element onto a second capacitive element to yield a sampled voltage, wherein the one of the first gate drive voltage and the second gate drive voltage is generated based on the sampled voltage.

11. A switched-mode power supply (SMPS) comprising:
a first transistor;
an inductive element coupled to the first transistor; and
a driver circuit including an output coupled to a gate of the first transistor and comprising:
a first capacitive element including a first terminal selectively coupled to a voltage rail; and
a second capacitive element including a first terminal selectively coupled to the first terminal of the first capacitive element, a second terminal of the second capacitive element being coupled to a source of the first transistor.

12. The SMPS of claim 11, wherein the driver circuit further comprises:
at least one first switch coupled between the voltage rail and the first terminal of the first capacitive element, the SMPS being configured to receive a supply voltage at a supply node, wherein the voltage rail is configured to have a voltage that is higher than the supply voltage of the SMPS by a preconfigured voltage;
at least one second switch coupled between the supply node of the SMPS and a second terminal of the first capacitive element;
at least one third switch coupled between the first terminal of the first capacitive element and the first terminal of the second capacitive element;
at least one fourth switch coupled between the second terminal of the first capacitive element and the second terminal of the second capacitive element; and
a driver including a first supply node and a second supply node coupled to the first terminal and the second terminal of the second capacitive element, respectively, and an output coupled to the gate of the first transistor.

13. The SMPS of claim 12, wherein the driver circuit further comprises:
a second transistor coupled between the second terminal of the first capacitive element and a reference potential node; and
a comparator including a first input coupled to a reference voltage (Vref) node, a second input coupled to the second terminal of the first capacitive element, and an output coupled to the gate of the second transistor.

14. The SMPS of claim 13, wherein the driver circuit further comprises a fifth switch coupled between the output of the comparator and the gate of the second transistor.

15. The SMPS of claim 13, wherein the driver circuit further comprises a fifth switch coupled between the gate and a source of the second transistor.

16. A method for voltage regulation, comprising:
sensing an output current of a switched-mode power supply (SMPS);
selecting one of a first gate drive voltage and a second gate drive voltage based on the output current of the SMPS, the first gate drive voltage being different than the second gate drive voltage;
generating the one of the first gate drive voltage and the second gate drive voltage based on the selection; and
providing the one of the first gate drive voltage and the second gate drive voltage to a gate of a transistor of the SMPS.

17. The method of claim 16, wherein selecting the one of the first gate drive voltage and the second gate drive voltage comprises:
selecting the first gate drive voltage based on the output current of the SMPS being less than or equal to a first current threshold; or
selecting the second gate drive voltage based on the output current of the SMPS being greater than the first current threshold, the second gate drive voltage being greater than the first gate drive voltage.

18. The method of claim 17, wherein the first gate drive voltage comprises a source voltage of the transistor plus a first preconfigured voltage.

19. The method of claim 18, wherein the second gate drive voltage comprises the source voltage of the transistor plus a second preconfigured voltage for the transistor, the second preconfigured voltage being greater than the first preconfigured voltage.

20. The method of claim 16, wherein generating the one of the first gate drive voltage and the second gate drive voltage comprises:
storing the one of the first gate drive voltage and the second gate drive voltage on a first capacitive element; and
sampling the one of the first gate drive voltage and the second gate drive voltage stored on the first capacitive element onto a second capacitive element to yield a sampled voltage, wherein the one of the first gate drive voltage and the second gate drive voltage is generated based on the sampled voltage.
